(19) United States
(12) Patent Application Publication
(10) Pub. No.: US 2016/0190457 A1
(43) Pub. Date: Jun. 30, 2016

(54) CONDUCTIVE POLYMER COMPOSITION, AND CONDUCTIVE POLYMER THIN FILM, ELECTRONIC DEVICE AND ORGANIC LIGHT-EMITTING DEVICE USING THE SAME

(71) Applicants: SAMSUNG DISPLAY CO., LTD., Yongin-City (KR); Korea Advanced Institute of Science and Technology, Daejeon (KR)

(72) Inventors: Jaekook HA, Yongin-City (KR); Bumjoon KIM, Yongin-City (KR)

(21) Appl. No.: 14/741,668

(22) Filed: Jun. 17, 2015

(30) Foreign Application Priority Data
Dec. 30, 2014 (KR) 10-2014-0193849

(51) Int. Cl. H01L 51/00

(52) U.S. Cl. CPC H01L 51/0035; H01L 51/0037; H01L 51/5092

(57) ABSTRACT

A conductive polymer composition, including a polymer nanoparticle solution; and a conductive polymer solution, the polymer nanoparticle solution containing polymer nanoparticles in a concentration range of about 0.5 wt/vol % to about 2 wt/vol %, the conductive polymer solution containing a conductive polymer in a concentration range of about 1 wt/vol % to about 3 wt/vol %, and the polymer nanoparticle solution being included in the composition in an amount range of about 10% by volume to about 80% by volume, with respect to a total volume of the conductive polymer composition.

### CROSS-REFERENCE TO RELATED APPLICATION

Korean Patent Application No. 10-2014-0193849, filed on Dec. 30, 2014, in the Korean Intellectual Property Office, and entitled: “Conductive Polymer Composition, and Conductive Polymer Thin Film, Electronic Device and Organic Light-Emitting Device Using The Same,” is incorporated by reference herein in its entirety.

### BACKGROUND

1. Field

One or more exemplary embodiments relate to a conductive polymer composition, and a conductive polymer thin film, an electronic device, and an organic light-emitting device using the conductive polymer composition.

2. Description of the Related Art

Soluble organic light-emitting devices (OLEDs) may provide, for example, efficiencies of material uses and possibilities of large area display devices.

### SUMMARY

Embodiments may be realized by providing a conductive polymer composition, including a polymer nanoparticle solution; and a conductive polymer solution, the polymer nanoparticle solution containing polymer nanoparticles in a concentration range of about 0.5 wt/vol % to about 2 wt/vol %, the conductive polymer solution containing a conductive polymer in a concentration range of about 1 wt/vol % to about 3 wt/vol %, and the polymer nanoparticle solution being included in the composition in an amount range of about 10% by volume to about 80% by volume, with respect to a total volume of the conductive polymer composition.

The polymer nanoparticle solution may be a colloidal solution.

The polymer nanoparticle solution and the conductive polymer solution may include water as a solvent.

The polymer nanoparticles may be spherical particles having a diameter of about 60 nm to about 100 nm.

The polymer nanoparticles may include polystyrene, polymethyl methacrylate, poly(styrene-divinylbenzene), polyamide, poly(butyl methacrylate-divinylbenzene), or a mixture thereof.

The polymer nanoparticle solution may be included in the composition in an amount range of about 40% by volume to about 80% by volume, with respect to the total volume of the conductive polymer composition.

The polymer nanoparticles may have a core-shell structure in which metal nanoparticles are surrounded by a polymer.

The polymer nanoparticle solution may be included in the composition in an amount range of about 10% by volume to about 60% by volume, with respect to the total volume of the conductive polymer composition

The metal nanoparticles may include gold, silver, a gold/silver alloy, or platinum as a metal.

The polymer of the core-shell structure may include polystyrene, polymethyl methacrylate, poly(styrene-divinylbenzene), polyamide, poly(butyl methacrylate-divinylbenzene), or a mixture thereof.

The polymer nanoparticles having the core-shell structure may include a core having a diameter of about 30 nm to about 60 nm and a shell having a thickness of about 30 nm to about 40 nm.

The conductive polymer may include poly(3,4-ethylenedioxythiophene)/poly(4-styrenesulfonate), polyaniline/Camphorsulfonic acid, polyaniline/poly(4-styrenesulfonate), or polyaniline/dodecylbenzenesulfonic acid.

A conductive thin film may be formed of the conductive polymer composition, the conductive polymer thin film including colloid crystals of the polymer nanoparticles; and a conductive polymer that forms a conductive path between the colloid crystals of the polymer nanoparticles.

An electronic device may include the conductive thin film.

The electronic device may be an organic light-emitting device, an organic solar cell, an electrochromic display device, or an organic thin film transistor.

An organic light-emitting device, may include an anode, a cathode, and one or more organic layers formed between the anode and the cathode, the one or more organic layers including the conductive thin film.

The conductive thin film may be a hole injection layer, and the one or more organic layers may further include an emitting layer.

The one or more organic layers may further include one or more of a hole transport layer, an electron transport layer, or an electron injection layer.

### BRIEF DESCRIPTION OF THE DRAWINGS

Features will become apparent to those of ordinary skill in the art by describing in detail exemplary embodiments with reference to the attached drawings in which:

FIG. 1 illustrates a schematic diagram of polymer nanoparticles having a core-shell structure;

FIG. 2 illustrates a schematic cross-sectional view of an organic light-emitting device according to one embodiment;

FIG. 3 illustrates a schematic cross-sectional view of an organic light-emitting device according to an embodiment;

FIG. 4 illustrates a scanning electron microscope (SEM) image of a conductive polymer thin film of Preparation Example 13;

FIG. 5 illustrates a graph in which current densities vs. voltages of organic light-emitting devices of Comparative Example 3 and Manufacturing Examples 15 to 17 are measured;

FIG. 6 illustrates a graph in which luminance vs. voltages of the organic light-emitting devices of Comparative Example 3 and Manufacturing Examples 15 to 17 are measured;

FIG. 7 illustrates a graph in which relative efficiencies vs. driving time values of the organic light-emitting devices of Comparative Example 3 and Manufacturing Examples 15 to 17 are measured to represent lifetime values of the organic light-emitting devices;

FIG. 8 illustrates a graph in which current densities vs. voltages and luminance vs. voltages of organic light-emitting devices of Comparative Example 3 and Manufacturing Example 20 are measured; and

FIG. 9 illustrates a graph in which current efficiencies vs. current densities of the organic light-emitting devices of Comparative Example 3 and Manufacturing Example 20 are measured.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

As used herein, the term “and/or” includes any and all combinations of one or more of the associated listed items. Expressions such as “at least one of,” when preceding a list of elements, modify the entire list of elements and do not modify the individual elements of the list.

The thicknesses of layers and areas in the drawings may be exaggerated for clarity of illustration. Identical reference numbers all over the specification represent identical components.

A solvent in the present specification may also include a dispersion medium, and a solution may also include a dispersion solution.

A conductive polymer composition according to one or more exemplary embodiments is described in detail.

The conductive polymer composition according to one or more exemplary embodiments may include polymer nanoparticles, a conductive polymer, and a solvent (dispersion medium).

Examples of the conductive polymer may include poly(3,4-ethylene dioxythiophene) (PEDOT), polyaniline (PANI), polypyrrole (PPy), polythiophene (PT), polyacetylene, polyphenylene, poly(p-phenylene vinylene) (PPV), copolymers including these as their parts, and derivatives thereof or derivatives of copolymers thereof.

Examples of the conductive polymer may include PEDOT/PSS (poly(3,4-ethylenedioxythiophene)/poly(4-styrenesulfonate)), PANI/CSA (polyaniline/Camphorsulfonic acid), PANI/PSS (polyaniline/poly(4-styrenesulfonate)), and PANI/DBSA (polyaniline/dodecylbenzenesulfonic acid).

For example, the conductive polymer may be included in an aqueous solution state in a conductive polymer composition.

Examples of the polymer of the polymer nanoparticles may include polystyrene (PS), polymethyl methacrylate (PMMA), poly(styrene-divinylbenzene), polyamide, poly(butyl methacrylate-divinylbenzene) (PMBA), and mixtures thereof.

The polymer nanoparticles may be spherical particles having a diameter of about 60 nm to about 100 nm.

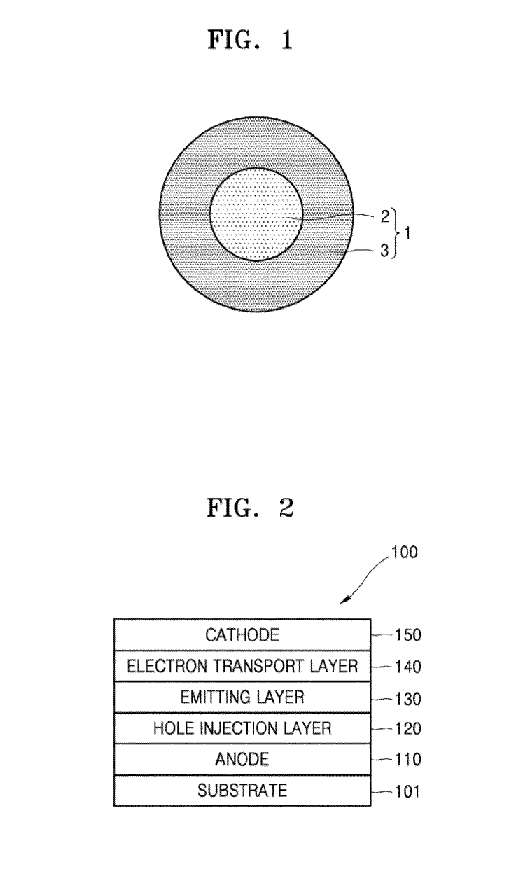

The polymer nanoparticles may have a core-shell structure in which metal nanoparticles are surrounded by the polymer. FIG. 1 a schematic diagram of polymer nanoparticles having a core-shell structure. Referring to FIG. 1, a core 2 as the metal nanoparticles may be surrounded by a shell 3 as the polymer in the polymer nanoparticles 1.

Examples of a metal of the core 2 in the polymer nanoparticles 1 may include gold, silver, a gold/silver alloy, and platinum. Examples of the shell 3 in the polymer nanoparticles 1 may include polystyrene (PS), polymethyl methacrylate (PMMA), poly(styrene-divinylbenzene), polyamide, poly(butyl methacrylate-divinylbenzene) (PMBA), and mixtures thereof.

For example, the polymer nanoparticles 1 having a core-shell structure may be polymer nanoparticles of the core-shell structure consisting of gold-polystyrene (Au—PS), silver-polystyrene (Ag—PS), gold/silver-polystyrene (Au/Ag—PS), or a mixture of a metal mentioned above as the core metal and a polymer mentioned above as the shell polymer.

The polymer nanoparticles 1 may have a metal core-polymer shell structure, and the surface Plasmon resonance phenomenon possessed by metal may further increase the efficiency of an organic light-emitting device. The polymer shell of the polymer nanoparticles may prevent metal nanoparticles of the core from reacting with the conductive polymer, and may control the size of the polymer nanoparticles.

For example, polymer nanoparticles 1 having a core-shell structure may include a core 2 having a diameter of about 30 nm to about 60 nm, and a shell having a thickness of about 30 nm to about 40 nm.

A conductive polymer composition may be formed from a mixture of a polymer nanoparticle solution and a conductive polymer solution. The polymer nanoparticle solution may be a solution in which polymer nanoparticles are dispersed in a solvent (dispersion medium). The polymer nanoparticle solution may be a colloidal solution. The conductive polymer solution may be a solution in which a conductive polymer may be dispersed in a solvent (dispersion medium). Solvents for the conductive polymer and the polymer nanoparticle solution may be identical compounds, e.g., water (deionized water). Therefore, for example, a solvent for a conductive polymer composition may be water.

The polymer nanoparticle solution may be contained in an amount range of about 10% by volume to about 80% by volume, and the conductive polymer solution may be contained in an amount range of about 20% by volume to about 90% by volume with respect to the total conductive polymer composition volume.

For example the polymer nanoparticles may be formed from a polymer only, the polymer nanoparticle solution may be contained in an amount range of about 40% by volume to about 80% by volume, e.g., 60% by volume to about 80% by volume, and the conductive polymer solution may be contained in an amount range of about 20% by volume to about 60% by volume, e.g., 20% by volume to about 40% by volume, with respect to the total conductive polymer composition volume. In an embodiment, the polymer nanoparticles may be formed in a metal core-polymer shell structure, the polymer nanoparticle solution may be contained in an amount range of about 10% by volume to about 60% by volume, e.g., 30% by volume to about 60% by volume, and the conductive polymer solution may be contained in an amount range of about 40% by volume to about 90% by volume, e.g., 40% by volume to about 70% by volume, with respect to the total conductive polymer composition volume.

In either case, e.g., the polymer nanoparticles are formed of a polymer only or the polymer nanoparticles have a core-shell structure, for example, the polymer nanoparticles may be contained in the polymer nanoparticle solution in a concentration range of about 0.5 wt/vol % to about 2 wt/vol %. For example, the conductive polymer may be contained in the conductive polymer solution in a concentration range of about 1 wt/vol % to about 3 wt/vol %. As used herein, the term wt/vol % means concentration in terms of weight per unit volume×100.

As an amount of the conductive polymer solution contained in the conductive polymer composition is decreased, an acidity of the conductive polymer composition may be decreased. When the acidity of the conductive polymer composition is decreased, a device including a conductive polymer thin film formed from the composition may have improved stability. Stability of a device may be secured although a larger amount of the conductive polymer solution is contained in the total composition when the polymer nanoparticles have a metal core-polymer shell structure compared to when the polymer nanoparticles are formed from a polymer only.

A conductive polymer thin film according to one or more exemplary embodiments is described in detail. The conductive polymer thin film may be formed from the above-described conductive polymer composition. For example, the conductive polymer thin film may be formed from the conductive polymer composition by various methods including spin coating, cast, Langmuir-Blodgett (LB), dip coating, screen printing, inkjet printing, and thermal transfer.

The conductive polymer thin film may include polymer nanoparticles and a conductive polymer. Descriptions of the polymer nanoparticles and the conductive polymer may be the same as the descriptions of the polymer nanoparticles and the conductive polymer in the conductive polymer composition of the above-mentioned exemplary embodiments.

The polymer nanoparticles may exist as a polymer colloid crystal within the conductive polymer thin film. Polymer colloid crystal may refer to a structure in which the polymer nanoparticles may be densely arranged in a periodic manner. For example, a polymer nanoparticle crystal may be formed of spherical particles having a diameter of about 60 nm to about 100 nm. The polymer nanoparticle crystal may form a body of the conductive polymer thin film.

The conductive polymer may be formed in chain forms and may be uniformly distributed between the polymer nanoparticles within the conductive polymer thin film, and the chain forms may be connected to form a conductive path within the conductive polymer thin film. The polymer nanoparticles may form a matrix, and the conductive polymer may be distributed within the matrix.

The polymer nanoparticles in the conductive polymer thin film may have an area ratio of about 20% to about 70%, e.g., about 40% to about 70%. The conductive polymer in the conductive polymer thin film may have an area ratio of about 30% to about 80%, e.g., about 30% to about 60%. In the present specification, the area ratio of the polymer nanoparticles in the conductive polymer thin film may be a ratio of an area occupied by the polymer nanoparticles to an area of the surface of a thin film that is parallel to a substrate. Likewise, in the present specification, the area ratio of the conductive polymer in the conductive polymer thin film may be a ratio of an area occupied by the conductive polymer to the area of the surface of the thin film that is parallel to the substrate.

Since the conductive polymer may represent, e.g., be, acidic, as the area ratio of the conductive polymer decreases, i.e., as the area ratio of the polymer nanoparticles increases, an acidity of the conductive polymer thin film may be decreased. If the acidity of the conductive polymer thin film is decreased, stability of the device may be improved. The polymer nanoparticles may be uniformly distributed without an aggregation phenomenon within the conductive polymer thin film according to one or more exemplary embodiments. The polymer nanoparticles may have a uniform size and may be evenly distributed in a stable state within a conductive polymer composition used for the formation of the conductive polymer thin film. A thin film may not be formed uniformly when the aggregation phenomenon is generated. When the polymer nanoparticles are uniformly distributed, the thin film may be uniformly formed to obtain, e.g., good thickness uniformity, and electric conductivity.

When the polymer nanoparticles have a metal core-polymer shell structure, an organic light-emitting diode may have increased efficiency by surface plasmon resonance of a metal core. The polymer shell of the polymer nanoparticles may prevent metal nanoparticles of the core from reacting with the conductive polymer, and may control the size of the polymer nanoparticles.

An organic light-emitting device according to one or more exemplary embodiments is described in detail.

FIG. 2 illustrates a schematic cross-sectional view of an organic light-emitting device according to one embodiment.

Referring to FIG. 2, an organic light-emitting device 100 may include a substrate 101, an anode 110, a hole injection layer 121, an emitting layer 130, an electron transport layer 141, and a cathode 150 that may be sequentially formed. Hereinafter, the respective layers of the organic light-emitting device 100 are described specifically.

Examples of the substrate 101 may include substrates that are used in ordinary organic light-emitting devices. The substrate 101 may be formed in a glass substrate or a transparent plastic substrate having excellent mechanical strength, thermal stability, transparency, surface flatness, handling easiness, and waterproofing property, and may be formed from opaque materials such as silicon and stainless steel.

The anode 110 may be formed on the substrate 101. Material for the anode 110 may be selected from materials having a high work function to facilitate hole injection.

The anode 110 may be a transmission type electrode or a reflection type electrode. Examples of the material for the anode 110 may include, e.g., indium tin oxide (ITO), indium zinc oxide (IZO), tin oxide (SnO₂), and zinc oxide (ZnO), that may be transparent and may have excellent conductivities. The anode 110 may be formed into a reflection type electrode by using, e.g., magnesium (Mg), silver (Ag), aluminum (Al), aluminum:lithium (Al:Li), calcium (Ca), silver:indium tin oxide (Ag:ITO), magnesium:indium (Mg:In), or magnesium:silver (Mg:Ag). Examples of the anode 110 may include a structure of a single layer or multiple layers of two or more layers. Examples of the anode 110 may include a structure of three layers ITO/Ag/ITO.

The hole injection layer 121 may be formed of the conductive polymer thin film described in the above-exemplary embodiments. When the hole injection layer is acidic, the anode may be degraded by the acidity, and emitted materials by degradation may be diffused into an adjacent organic layer, e.g., an emitting layer, and may result in decreases in efficiency and lifetime of an organic light-emitting device. Efficiency and lifetime of the organic light-emitting device may be improved since the hole injection layer 121 formed of the conductive polymer thin film may have excellent hole-injecting function and electric conductivity, and the acidity of the hole injection layer may be lowered, i.e., it may near a neutral state, and excellent safety of a thin film may not influence an adjacent organic layer.

An emitting layer (EML) 130 may be formed using various emitting materials or a host and a dopant generally used in the relevant art.

Examples of the host may include poly(N-vinyl carbazole) (PVK), poly(p-phenylene vinylene) (PPV), soluble PPV, cyano-PPV, polyfluorene, 4,4′-bis(9-carbazolyl)-2,2′-dimethyl-biphenyl (CDBP), N,N′-bis(3-methylphenyl)-N,N′-bis(phenyl)benzidine (TPD), 2-(4-biphenylyl)-5-(4-tert-butylphenyl)-1,3,4-oxadiazole (PBD), N,N′-dicarbazolyl-3,5-benzene (mCP), mCP derivatives, and mixtures thereof. The host may be formed using, e.g., anthracene derivatives, pyrene derivatives, or perylene derivatives.

Examples of a red dopant may include Pt(II) octaethylporphine (PtOEP), tris(2-phenylisoquinoline)iridium (Ir(piq)₃), bis[2-(2′-benzothienyl)-pyridinato-N,C3′]iridium(acetylacetonate) (Btp₂Ir(acac)), bis(1-phenylisoquinoline) (acetylacetonate)iridium(III) (Ir(piq)₂(acac)), 4-(dicyanomethylene)-2-methyl-6-(p-dimethylamino-styryl)-4H-pyran (DCM),and 4-(dicyanomethylene)-2-tert-butyl-6(1,1,7,7-tetramethyljulolidyl-9-enyl)-4H-pyran (DCJTB).

Examples of a green dopant may include tris(2-phenylpyridine)iridium (Ir(ppy)₃), bis(2-phenylpyridine)(acetylacetonato)iridium(III) (Ir(ppy)₂(acac), tris(2-(4-tolyl)phenylpyridine)iridium (Ir(mppy)₃), and 10-(2-benzothiazolyl)-1,1,7,7-tetramethyl-2,3,6,7-tetrahydro-1H,5H,11H-[1]benzopyrano[6,7,8-ij]-quinolizin-11-one (C545T).

Examples of a blue dopant may include bis[3,5-difluoro-2-(2-pyridyl)phenyl](picolinato)iridium(III) (F₂Irpic), (F₂ppy)₂Ir(tmd), Ir(dfppz)₃, 4,4-bis(2,2-diphenylethen-1-yl)biphenyl (DPVBi), and 4,4′-bis[4-(diphenylamino)styryl]biphenyl (DPAVBi), 2,5,8,11-tetra-tert-butyl perylene (TBPe).

The emitting layer 130 may be formed by various methods such as, e.g., deposition, spin coating, cast, Langmuir-Blodgett (LB), dip coating, screen printing, inkjet printing, and thermal transfer. The emitting layer 130 may include a host and a dopant, and the dopant may be selectively contained in an amount range of, for example, about 0.01 part by weight to about 15 part by weights generally based on the total host weight of about 100 part by weights. In an embodiment, the emitting layer 130 may have a thickness range of about 100 Å to about 800 Å, e.g., about 200 Å to about 600 Å.

The electron transport layer 141 is on the emitting layer 130, and examples of the electron transport layer 141 may include low molecular weight materials such as tris(8-hydroxyquinoline)aluminum(III) (Alq3), 2,9-dimethyl-4,7-diphenyl-1,10-phenanthroline (BCP), 4 7-diphenyl-1,10-phenanthroline (BPhen), 2,2′,2″-(1,3,5-benzenetriyl)tris[1-phenyl-1H-benzimidazole] (TPBI), 3-(4-biphenylyl)-4-phenyl-5-(4-tert-butylphenyl)-1,2,4-triazole (TAZ), 4-(naphthalene-1-yl)-3,5-diphenyl-4H-1,2,4-triazole (NTAZ), 2-(4-biphenyl)-5-(4-tert-butylphenyl)-1,3,4-oxadiazole (butyl-PBD), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), and beryllium bis(benzoquinolin-10-olate (Bebq2), 9,10-di(naphthalene-2-yl)anthracene (ADN).

Examples of the electron transport layer 141 may include may include high molecular materials such as poly(p-phenylene vinylene) (PPV), polythiophene (PT), poly[(9,9-dihexylfluorene-2,7-diyl)-co-(pyridine-3,5-diyl)] (PF-Py), and poly[(9,9-dioctylfluorene-2,7-diyl)-co-(2,2′-bipyridine-3,5-diyl)] (PF-Bpy).

The electron transport layer 141 may be formed by various methods such as, e.g., deposition, spin coating, cast, Langmuir-Blodgett (LB), dip coating, screen printing, inkjet printing, and thermal transfer. The electron transport layer 141 may have a thickness range of about 100 Å to about 1,000 Å, e.g., about 150 Å to about 500 Å.

A cathode 150 may be formed on the electron transport layer 141. The cathode 150 may be formed from metals, alloys and electric conductive compounds having low work functions, or mixtures thereof. For example, the cathode 150 may be formed from materials including lithium (Li), magnesium (Mg), aluminum (Al), aluminum-lithium (Al—Li), calcium (Ca), magnesium-indium (Mg—In), and magnesium-silver (Mg—Ag). Diverse modifications may be made to obtain a front light-emitting device by forming a transmission type electrode using thin films of the above-mentioned materials or forming the transmission type electrode using ITO and IZO. For example, the cathode 150 may be formed by a vacuum deposition method. For example, the cathode 150 may have a thickness range of about 20 Å to about 300 Å, or about 50 Å to about 200 Å.

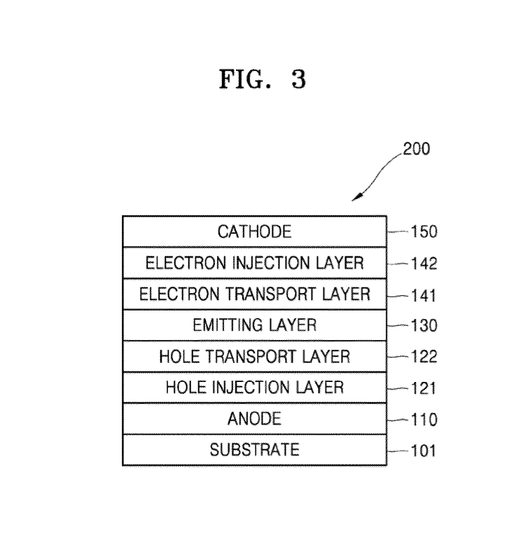

FIG. 3 illustrates a schematic cross-sectional view of an organic light-emitting device 200 according to an embodiment.

The organic light-emitting device 200 of FIG. 3 may be different from the organic light-emitting device 100 of FIG. 2 in that the organic light-emitting device 200 may additionally include a hole transport layer 122 and an electron injection layer 142.

The hole transport layer 122 may be a layer including material having high hole transporting properties. Examples of the material having high hole transporting properties may include aromatic amine compounds such as 4,4′-bis[N-(1-naphthyl)-N-phenylamino]biphenyl (NPB), N,N′-diphenyl-N,N′-bis(3-methylphenyl)-(1,1′-biphenyl)-4,4′-diamine (TPD), 4,4′,4″-tris(N,N-diphenylamino)triphenylamine (TDATA), 4,4′,4″-tris(N-3-methylphenyl-N-phenylamino)triphenylamine (MTDATA), and 4,4′-bis[N-(spiro-9,9′-bifluorene-2-yl)-N-phenylamino]biphenyl (BSPB). Examples of the material as the hole transport layer 122 may additionally include high molecular weight compounds such as poly(N-vinylcarbazole) (PVK), poly(-vinylcarbazole), poly(4-vinyltriphenylamine) (PVTPA), poly[N-(4-{N′-[4-(4-diphenylamino)phenyl]phenyl-N-phenylamino}phenyl)methacrylamide (PTPDMA), and poly[N,N′-bis(4-butylphenyl)-N,N′-bis(phenyl)-benzidine (Poly-TPD).

The hole transport layer 122 may be formed by various methods such as, e.g., deposition, spin coating, cast, Langmuir-Blodgett (LB), dip coating, screen printing, inkjet printing, and thermal transfer. The hole transport layer 122 may have a thickness range of about 50 Å to about 1,000 Å, e.g., about 100 Å to about 800 Å.

Examples of the electron injection layer 142 may include materials such as BaF₂, LiF, NaCl, CsF, Li₂O, BaO, and LiQ. The electron injection layer 142 may have a thickness range of about 0.2 nm to about 10 nm. For example, the electron injection layer 142 may be formed by a vacuum deposition method. The electron injection layer 142 may have a thickness range of about 1 Å to about 100 Å, or about 5 Å to about 70 Å.

Although an organic light-emitting device has been exemplified as having a structure of substrate/anode/hole injection layer/emitting layer/electron transport layer/cathode or a structure of substrate/anode/hole injection layer/hole transport layer/emitting layer/electron transport layer/electron injection layer/cathode, the hole transport layer, electron transport layer or electron injection layer may be omitted or added. Examples of the structure may include a structure of substrate/anode/hole injection layer/emitting layer/cathode, a structure of substrate/anode/hole injection layer/emitting layer/electron injection layer/cathode, a structure of substrate/anode/hole injection layer/hole transport layer/emitting layer/electron transport layer/cathode, and a structure of substrate/anode/hole injection layer/hole transport layer/emitting layer/electron injection layer/cathode. Examples of the structure may additionally include a structure in which other layers may be added between the anode and the cathode. An inverted organic light-emitting device formed from the cathode side may be formed on the substrate.

The conductive polymer thin film may be used in electronic devices such as organic solar cells, electrochromic display devices, organic thin film transistors in addition to the hole injection layer of the organic light-emitting device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### SYNTHESIS EXAMPLE 1

### Preparation of a Polystyrene Nanoparticle Solution

Styrene monomers were refined by an aluminum oxide column. 1 g of the refined styrene monomers, 100 mg of polyvinylpyrrolidone (PVP) as a surfactant and 60 mg of divinylbenzene (DVB) as a cross-linking agent were mixed and stirred to obtain a mixture. 80 ml of deionized water was put into the mixture, and the mixture added with the deionized water was stirred in a reactor of 70° C. for one hour. Thereafter, 57.5 mg of azobisisobutyronitrile (AIBN) as an initiator was put into and reacted with the mixture, for 24 hours, and the mixture was cooled to room temperature to form polystyrene nanoparticles. In order to remove styrene monomers, PVP and DVB remained after filtering the produced polystyrene nanoparticles, the polystyrene nanoparticles were refined by repeatedly performing the centrifugal process using methanol and deionized water. The refined polystyrene nanoparticles were dispersed into water to keep a polystyrene nanoparticle solution. The polystyrene nanoparticles were contained in the polystyrene nanoparticle solution in a concentration of about 1 wt/vol %.

### COMPARATIVE EXAMPLE 1

### Preparation of a Conductive Polymer Composition

Only an aqueous solution having a concentration of about 1.5 wt/vol % of PEDOT:PSS (Product Name A14083 produced by Heraeus Corporation) was used as a conductive polymer composition.

### PREPARATION EXAMPLES 1 TO 7

### Preparation of Conductive Polymer Compositions

Aqueous solutions having a concentration of about 1.5 wt/vol % of PEDOT:PSS (Product Name A14083 produced by Heraeus Corporation) were used as a conductive polymer composition. The polystyrene nanoparticle solution of Synthesis Example 1 was mixed with the PEDOT:PSS solutions, and the mixtures were filtered to prepare conductive polymer compositions. Preparation Examples 1 to 7 were performed by varying volumes of the polystyrene nanoparticle solution and the PEDOT:PSS conductive polymer solutions, wherein ratios (Φ_{PS}) of a volume of the polystyrene nanoparticle solution to total conductive polymer composition volumes were 0.3, 0.4, 0.5, 0.6, 0.75, 0.8, and 0.9; and ratios (Φ_{PEDOT:PSS}) of volumes of the PEDOT:PSS solutions to total conductive polymer composition volumes were 0.7, 0.6, 0.5, 0.4, 0.25, 0.2, and 0.1. The volume ratios of the polystyrene nanoparticle solution and the PEDOT:PSS solutions in the conductive polymer compositions of Comparative Example 1 and Preparation Examples 1 to 7 are presented in Table 1.

TABLE 1

| Conductive | Volume ratio (Φ_{PS}) | Volume ratios |
|---|---|---|
| polymer | of the polystyrene | (Φ_{PEDOT:PSS}) of the |
| compositions | nanoparticle solution | PEDOT:PSS solutions |
| Comparative | 0 | 1 |
| Example 1 | | |
| Preparation | 0.3 | 0.7 |
| Example 1 | | |
| Preparation | 0.4 | 0.6 |
| Example 2 | | |
| Preparation | 0.5 | 0.5 |
| Example 3 | | |
| Preparation | 0.6 | 0.4 |
| Example 4 | | |
| Preparation | 0.75 | 0.25 |
| Example 5 | | |
| Preparation | 0.8 | 0.2 |
| Example 6 | | |
| Preparation | 0.9 | 0.1 |
| Example 7 | | |

### COMPARATIVE EXAMPLE 2

### Formation of a Conductive Polymer Thin Film

The conductive polymer composition (Φ_{PS}=0) of Comparative Example 1 was dropped onto a glass substrate coated with indium tin oxide (ITO) to perform a process of spin-coating the conductive polymer composition on the ITO coated glass substrate at a speed of 2,000 rpm for 40 seconds. The substrate was heated on a hot plate of 150° C. for 15 minutes to form a conductive polymer thin film having a thickness of about 50 nm.

### PREPARATION EXAMPLES 8 TO 14

### Formation of Conductive Polymer Thin Films

Conductive polymer thin films of Preparation Examples 8 to 14 were formed by the same method as in Comparative Example 2 except that the conductive polymer compositions of Preparation Examples 1 to 7 instead of the conductive polymer composition (Φ_{PS}=0) of Comparative Example 1 were used.

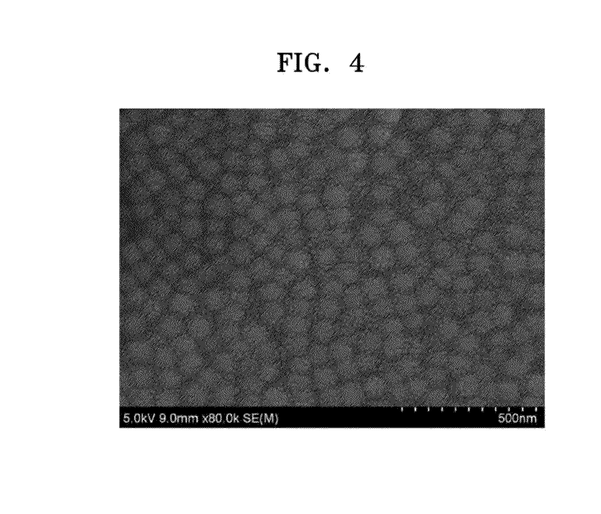

FIG. 4 illustrates an SEM image of a conductive polymer thin film (Φ_{PS}=0.8) of Preparation Example 13. In the image of FIG. 4, polystyrene nanoparticles were uniformly distributed within the conductive polymer thin film. PEDOT:PSS existed between and/or on the polystyrene nanoparticles.

Area ratios of polystyrene nanoparticles, area ratios of PEDOT:PSS and number densities of the polystyrene nanoparticles in conductive polymer thin films of Comparative Example 2 and Preparation Examples 9, 11 and 13 are presented in Table 2. The area ratios are the same as described in the present specification, and the number densities are the number of the polystyrene nanoparticles included within an area of 1 cm².

TABLE 2

| Conductive | Area ratios (r_{A}, _{PS}) | Area ratios | Number densities | |
|---|---|---|---|---|
| polymer | of polystyrene | (r_{A, PEDOT:PSS}) | (N_{PS}) of polystyrene | |
| thin films | nanoparticles | of PEDOT:PSS | nanoparticles | |
| Comparative | 0 | 1 | 0 | cm⁻² |
| Example 2 | | | | |
| Preparation | 0.25 | 0.75 | 6.4 × 10⁹ | cm⁻² |
| Example 9 | | | | |
| Preparation | 0.45 | 0.55 | 11.7 × 10⁹ | cm⁻² |
| Example 11 | | | | |
| Preparation | 0.62 | 0.38 | 15.9 × 10⁹ | cm⁻² |
| Example 13 | | | | |

### COMPARATIVE EXAMPLE 3

### Manufacturing of an Organic Light-Emitting Device

After ultrasonic cleaning an ITO coated glass substrate using acetone, deionized water, and isopropyl alcohol respectively for 15 minutes, the ultrasonic cleaned ITO substrate was subjected to UV ozone cleaning for 15 minutes. The cleaned ITO substrate was subjected to oxygen plasma treatment at a condition of 100 W for 30 minutes. The conductive polymer composition (Φ_{PS}=0) of Comparative Example 1 was dropped onto the plasma treated substrate to spin coat the plasma treated substrate with the conductive polymer composition at a speed of 2,000 rpm for 40 seconds. The substrate was heated on a hot plate of 150° C. for 15 minutes to evaporate solvent remained on the conductive polymer thin film. At this time, the conductive polymer thin film as a hole injection layer was formed to a thickness of about 50 nm.

A mixed solution of 18.9 mg of PVK, 8.1 mg of PBD and 0.7 mg of Ir(ppy)₃ was dropped onto the hole injection layer, and was spin coated at a speed of 1,200 rpm for 40 seconds to form an emitting layer having a thickness of about 100 nm. The organic light-emitting device of Comparative Example 3 was manufactured by vapor depositing LiF and Al on the emitting layer, thereby forming upper electrode layers respectively having thicknesses of about 1 nm and about 100 nm. The hole injection layer of the organic light-emitting device of Comparative Example 3 corresponds to the conductive polymer thin film of Comparative Example 2.

### MANUFACTURING EXAMPLES 15 TO 17

### Manufacturing of Organic Light-Emitting Devices

Organic light-emitting devices of Manufacturing Examples 15, 16 and 17 were manufactured by the same method as the method of manufacturing the organic light-emitting device of Comparative Example 3 except that the conductive polymer compositions (Φ_{PS}=0.4, 0.6, and 0.8) of Preparation Examples 2, 4 and 6 were used respectively instead of the conductive polymer composition of Comparative Example 1. Hole injection layers of the organic light-emitting devices of Manufacturing Examples 15, 16 and 17 correspond to the conductive polymer thin films of Preparation Examples 9, 11 and 13 respectively.

Characteristics of the organic light-emitting devices (Manufacturing Examples 15 to 17)

Current-voltage characteristics, luminance and lifetime of the organic light-emitting devices of Comparative Example 3 and Manufacturing Examples 15 to 17 were measured.

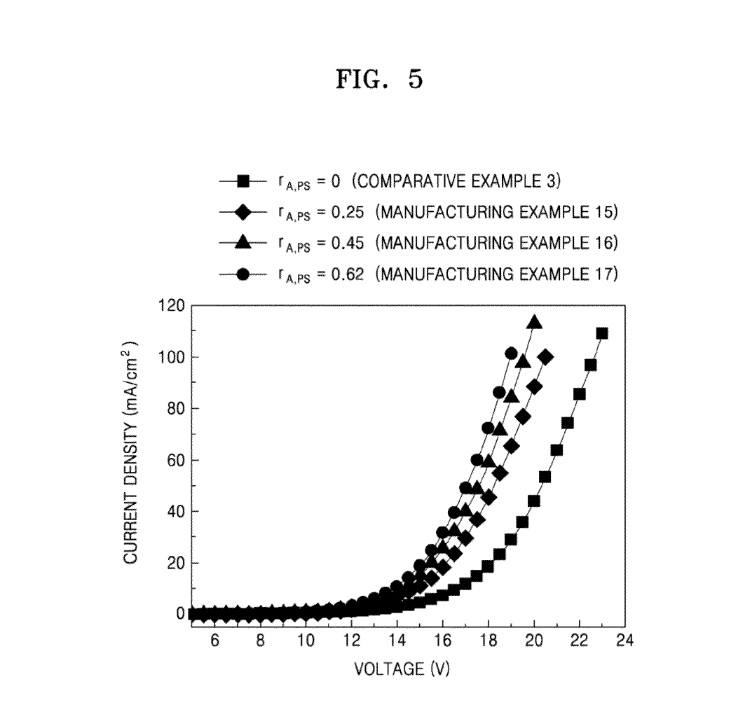

FIG. 5 illustrates a graph in which current densities vs. voltages of the organic light-emitting devices of Comparative Example 3 and Manufacturing Examples 15 to 17 are measured. Referring to the graph of FIG. 5, current densities were higher at the same voltage in the organic light-emitting devices of Manufacturing Examples 15 to 17 in which polystyrene nanoparticles were included than the organic light-emitting device of Comparative Example 3 in which the polystyrene nanoparticles were not included. The organic light-emitting devices had high current densities at the same voltage as the area ratios (rA,PS) of the polystyrene nanoparticles were increased in the order of 0.25, 0.45 and 0.62.

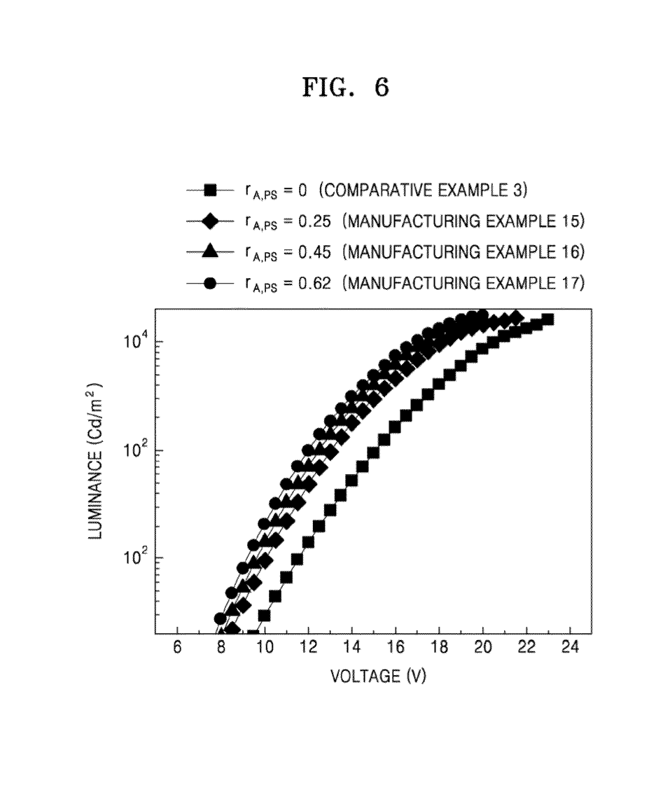

FIG. 6 illustrates a graph in which luminance vs. voltages of the organic light-emitting devices of Comparative Example 3 and Manufacturing Examples 15 to 17 are measured. Referring to the graph of FIG. 6, luminance were higher at the same driving voltage in the organic light-emitting devices of Manufacturing Examples 15 to 17 in which the polystyrene nanoparticles were included than the organic light-emitting device of Comparative Example 3 in which the polystyrene nanoparticles were not included. The organic light-emitting devices had high luminance at the same driving voltage as the area ratios (Φ) of the polystyrene nanoparticles were increased in the order of 0.25, 0.45 and 0.62.

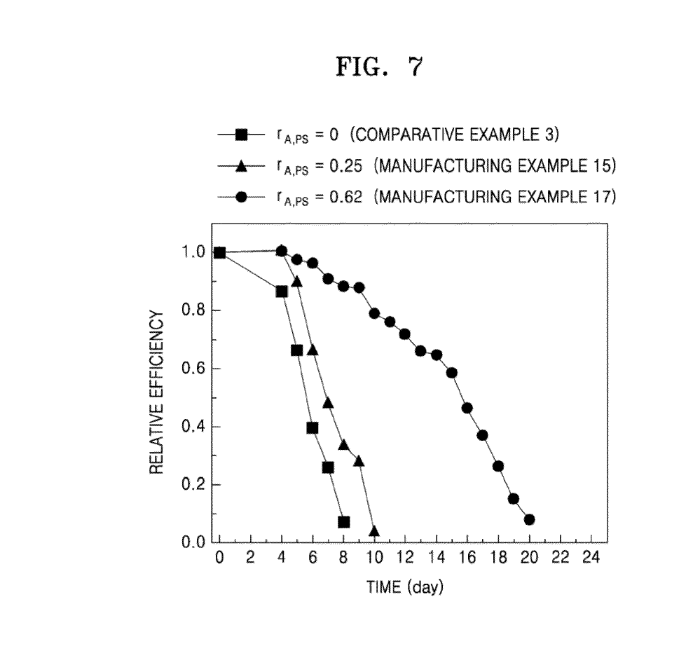

FIG. 7 illustrates a graph in which relative efficiencies vs. driving time of the organic light-emitting devices of Comparative Example 3 and Manufacturing Examples 15 to 17 are measured to represent lifetime of the organic light-emitting devices. The relative efficiencies in the graph of FIG. 7 are obtained by dividing efficiencies at each time of the respective organic light-emitting devices by efficiency of the first driving process. The efficiencies are current efficiencies. Referring to the graph of FIG. 7, lifetime were higher in the organic light-emitting devices of Manufacturing Examples 15 to 17 in which the polystyrene nanoparticles were included than the organic light-emitting device of Comparative Example 3 in which the polystyrene nanoparticles were not included. The organic light-emitting devices had high luminance at the same driving voltage as the area ratios (Φ) of the polystyrene nanoparticles were increased in the order of 0.25 and 0.62.

### SYNTHESIS EXAMPLE 2

### Synthesis of Polystyrene-Coated Gold (Au) Nanoparticles

In order to synthesize gold (Au) nanoparticles, 10 mg of HAuCl₄ as a gold precursor was dissolved into 100 ml of a tertiary deionized water to stir the gold precursor HAuCl₄ and the tertiary deionized water until the tertiary deionized water was boiled in a reactor of 100° C. After putting 7 mg of sodium citrate that was simultaneously performing roles of a reducing agent and a surface stabilizing agent for gold (Au) nanoparticles into the stirred material and reacting sodium citrate with the stirred material for 5 minutes, the reactor was cooled to room temperature to form a gold nanoparticle solution.

Styrene monomers were refined by an aluminum oxide column. 0.95 ml of the refined styrene monomers, 300 mg of PVP as a surfactant and 0.05 ml of DVB as a cross-linking agent were mixed and stirred to obtain a mixture. 82.5 ml of ethanol and 22.5 ml of deionized water were put into the mixture, and the ethanol, the deionized water and the mixture were stirred in a reactor of 70° C. for one hour. Thereafter, 50 mg of 2,2′-azobis(2-amidinopropane)dihydrochloride (AIBA) as an initiator was put into a reactor, the initiator AIBA and the resulting material were stirred for 8 minutes, 15 ml of the above-synthesized gold (Au) nanoparticle solution was put into the stirred material to react the gold (Au) nanoparticle solution with the initiator AIBA for 24 hours to obtain a mixture, and the mixture was cooled to room temperature to produce polystyrene-coated gold (Au) nanoparticles. In order to remove styrene monomers, PVP and DVB remained after filtering the produced polystyrene-coated gold (Au) nanoparticles, the polystyrene-coated gold (Au) nanoparticles were refined by repeatedly performing the centrifugal process using methanol and deionized water. The refined polystyrene-coated gold (Au) nanoparticles were dispersed into water to keep a polystyrene-coated gold (Au) nanoparticle solution. The polystyrene-coated gold (Au) nanoparticles were contained in the polystyrene nanoparticle solution in a concentration of 1 wt/vol %.

### PREPARATION EXAMPLE 18

### Preparation of a Conductive Polymer Composition

An aqueous solution having a concentration of 1.5 wt/vol % of PEDOT:PSS (Product Name A14083 produced by Heraeus Corporation) was used as a conductive polymer solution. The gold (Au) nanoparticle solution coated with polystyrene synthesized in the synthesis Example 2 was mixed with the PEDOT:PSS solution at a volume ratio of 7:3, and the mixtures were filtered to prepare a conductive polymer composition. Volume ratios of the polystyrene-coated gold (Au) nanoparticle solutions and the PEDOT:PSS solutions in the conductive polymer compositions with respect to the total conductive polymer composition volume of Comparative Example 1 and Preparation Example 18 are presented in Table 3.

TABLE 3

| Conductive | Volume ratio (Φ_{PS}) of the | Volume ratio |
|---|---|---|
| polymer | polystyrene-coated gold | (Φ_{PEDOT:PSS}) of the |
| compositions | nanoparticle solutions | PEDOT:PSS solutions |
| Comparative | 0 | 1 |
| Example 1 | | |
| Preparation | 0.3 | 0.7 |
| Example 18 | | |

### PREPARATION EXAMPLE 19

### Formation of a Conductive Polymer Thin Film

The conductive polymer thin film of Preparation Examples 19 was formed by the same method as in Comparative Example 2 except that the conductive polymer composition of Preparation Example 18 instead of the conductive polymer composition (Φ_{PS}=0) of Comparative Example 1 was used.

Number densities of polystyrene nanoparticle-coated gold (Au) nanoparticles in conductive polymer thin films of Comparative Example 2 and Preparation Examples 19 are presented in Table 4.

TABLE 4

| Conductive | Number densities (N_{PS}) of | |
|---|---|---|
| polymer | polystyrene-coated gold | |
| thin films | (Au) nanoparticles | |
| Comparative | 0 | cm⁻² |
| Example 2 | | |
| Preparation | 1.3 × 10⁷ | cm⁻² |
| Example 19 | | |

### MANUFACTURING EXAMPLE 20

### Manufacturing of Organic Light-Emitting Device

An organic light-emitting device of Manufacturing Example 20 was manufactured by the same method as the method of manufacturing the organic light-emitting device of Comparative Example 3 except that the conductive polymer composition (Φ_{PS}=0.3) of Preparation Example 18 was used instead of the conductive polymer composition of Comparative Example 1. A hole injection layer of the organic light-emitting device of Manufacturing Examples 20 corresponds to the conductive polymer thin film of Preparation Examples 19.

Characteristics of the organic light-emitting devices (Manufacturing Example 20)

Current-voltage characteristics, luminance and efficiencies of the organic light-emitting devices of Comparative Example 3 and Manufacturing Example 20 were measured.

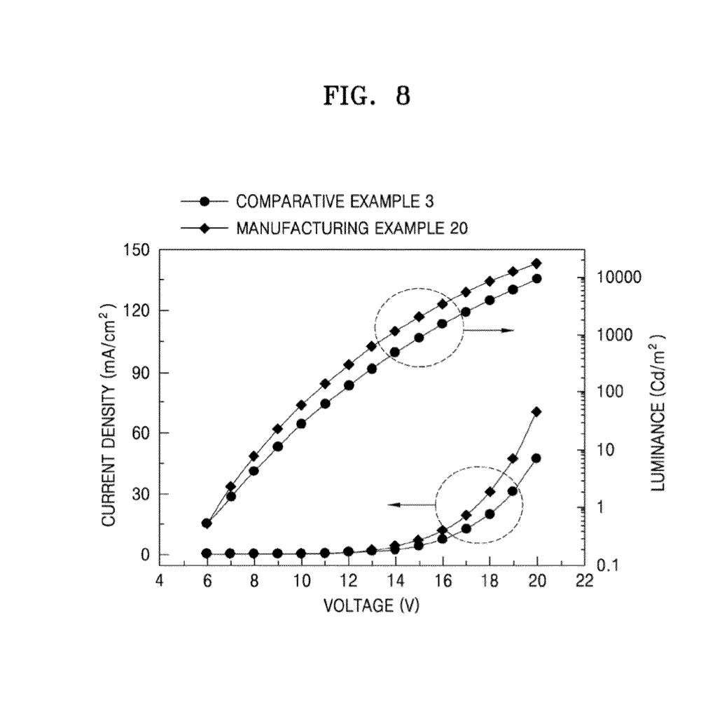

FIG. 8 illustrates a graph in which current densities vs. voltages and luminance vs. voltages of organic light-emitting devices of Comparative Example 3 and Manufacturing Example 20 are measured. Referring to the graph of FIG. 8, current density and luminance value were higher at the same voltage in the organic light-emitting device of Manufacturing Example 20 in which polystyrene-coated gold (Au) nanoparticles were included than the organic light-emitting device of Comparative Example 3 in which the polystyrene-coated gold (Au) nanoparticles were not included.

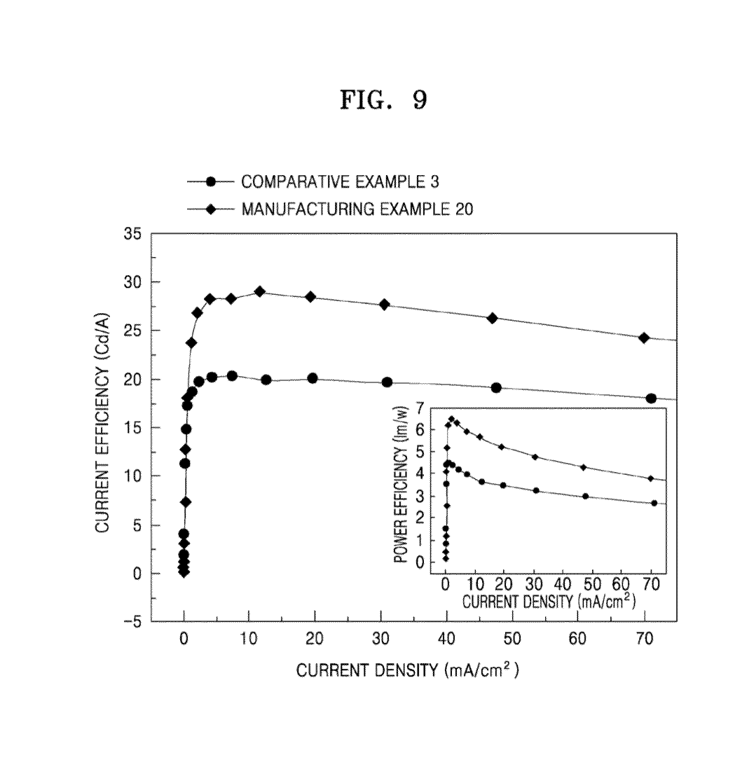

FIG. 9 illustrates a graph in which current efficiencies vs. current densities of the organic light-emitting devices of Comparative Example 3 and Manufacturing Example 20 are measured. A small graph within the graph of FIG. 9 illustrates a graph in which power efficiency vs. current density of the organic light-emitting device are measured. Referring to the graph of FIG. 9, both current efficiency and power efficiency were higher at the same current density in the organic light-emitting device of Manufacturing Example 20 in which the polystyrene-coated gold (Au) nanoparticles were included than the organic light-emitting device of Comparative Example 3 in which the polystyrene-coated gold (Au) nanoparticles were not included.

As examined in the above test results of the organic light-emitting devices, current-voltage characteristics and emitting characteristics were improved in devices in which the polystyrene nanoparticles were included than devices in which the polystyrene nanoparticles were not included. From evaluation results of atmospheric stabilities at the same condition of the organic light-emitting devices, atmospheric stabilities were improved in the devices in which the polystyrene nanoparticles were included than the devices in which the polystyrene nanoparticles were not included.

From measurement results of characteristics of the organic light-emitting devices, current-voltage characteristics and efficiency characteristics were improved in organic light-emitting devices in which the polystyrene-coated gold (Au) nanoparticles (hybrid nanoparticles) were included than organic light-emitting devices in which the polystyrene-coated gold (Au) nanoparticles (hybrid nanoparticles) were not included. The devices in which the hybrid nanoparticles were included could obtain results that driving voltages were decreased, and efficiencies were increased 1.5 times or more compared to the devices in which the hybrid nanoparticles were not included.

By way of summation and review, a poly(3,4-ethylenedioxythiophene) (PEDOT): poly(4-styrenesulfonate) (PSS) used as a hole injection layer in a soluble OLEDs may damage lifetime values and stabilities of the devices, for example, due to a high acidity (pH=1) and a high hygroscopicity. Although the content of PSS, which is a polymer acid, may be controlled to lower acidity, conductivity may be radically decreased. Although a silver (Ag) thin film may be used on the hole injection layer to improve conductivity, silver (Ag) may be oxidized by PEDOT:PSS.

One or more exemplary embodiments may include a conductive polymer composition that may be capable of improving lifetime and stability of the device, and a conductive polymer thin film, an electronic device, and an organic light-emitting device.

As described above, according to the one or more of the above exemplary embodiments, the organic light-emitting device may have improved lifetime and stability by forming a hole injection layer from a conductive polymer composition including a conductive polymer and polymer nanoparticles.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A conductive polymer composition, comprising:
a polymer nanoparticle solution; and
a conductive polymer solution,
the polymer nanoparticle solution containing polymer nanoparticles in a concentration range of about 0.5 wt/vol % to about 2 wt/vol %,
the conductive polymer solution containing a conductive polymer in a concentration range of about 1 wt/vol % to about 3 wt/vol %, and
the polymer nanoparticle solution being included in the composition in an amount range of about 10% by volume to about 80% by volume, with respect to a total volume of the conductive polymer composition.

2. The conductive polymer composition as claimed in claim 1, wherein the polymer nanoparticle solution is a colloidal solution.

3. The conductive polymer composition as claimed in claim 1, wherein the polymer nanoparticle solution and the conductive polymer solution include water as a solvent.

4. The conductive polymer composition as claimed in claim 1, wherein the polymer nanoparticles are spherical particles having a diameter of about 60 nm to about 100 nm.

5. The conductive polymer composition as claimed in claim 1, wherein the polymer nanoparticles include polystyrene, polymethyl methacrylate, poly(styrene-divinylbenzene), polyamide, poly(butyl methacrylate-divinylbenzene), or a mixture thereof.

6. The conductive polymer composition as claimed in claim 5, wherein the polymer nanoparticle solution is included in the composition in an amount range of about 40% by volume to about 80% by volume, with respect to the total volume of the conductive polymer composition.

7. The conductive polymer composition as claimed in claim 1, wherein the polymer nanoparticles have a core-shell structure in which metal nanoparticles are surrounded by a polymer.

8. The conductive polymer composition as claimed in claim 7, wherein the polymer nanoparticle solution is included in the composition in an amount range of about 10% by volume to about 60% by volume, with respect to the total volume of the conductive polymer composition.

9. The conductive polymer composition as claimed in claim 7, wherein the metal nanoparticles include gold, silver, a gold/silver alloy, or platinum as a metal.

10. The conductive polymer composition as claimed in claim 9, wherein the polymer of the core-shell structure includes polystyrene, polymethyl methacrylate, poly(styrene-divinylbenzene), polyamide, poly(butyl methacrylate-divinylbenzene), or a mixture thereof.

11. The conductive polymer composition as claimed in claim 7, wherein the polymer nanoparticles having the core-shell structure include a core having a diameter of about 30 nm to about 60 nm and a shell having a thickness of about 30 nm to about 40 nm.

12. The conductive polymer composition as claimed in claim 1, wherein the conductive polymer includes poly(3,4-ethylenedioxythiophene)/poly(4-styrenesulfonate), polyaniline/Camphorsulfonic acid, polyaniline/poly(4-styrenesulfonate), or polyaniline/dodecylbenzenesulfonic acid.

13. A conductive thin film formed of the conductive polymer composition as claimed in claim 1, the conductive polymer thin film including:
colloid crystals of the polymer nanoparticles; and
a conductive polymer that forms a conductive path between the colloid crystals of the polymer nanoparticles.

14. An electronic device comprising the conductive thin film as claimed in claim 13.

15. The electronic device as claimed in claim 14, wherein the electronic device is an organic light-emitting device, an organic solar cell, an electrochromic display device, or an organic thin film transistor.

16. An organic light-emitting device, comprising an anode, a cathode, and one or more organic layers formed between the anode and the cathode, the one or more organic layers including the conductive thin film as claimed in claim 13.

17. The organic light-emitting device as claimed in claim 16, wherein:
the conductive thin film is a hole injection layer, and
the one or more organic layers further include an emitting layer.

18. The organic light-emitting device as claimed in claim 17, wherein the one or more organic layers further include one or more of a hole transport layer, an electron transport layer, or an electron injection layer.
